(19) United States
(12) Patent Application Publication
(10) Pub. No.: US 2026/0187505 A1
(43) Pub. Date: Jul. 2, 2026

(54) PROBABILISTIC-BIT DEVICE WITH A WIDE INPUT RANGE

(71) Applicants: COMMISSARIAT À L'ENERGIE ATOMIQUE ET AUX ENERGIES ALTERNATIVES, PARIS (FR); CENTRE NATIONAL DE LA RECHERCHE SCIENTIFIQUE, PARIS (FR); UNIVERSITE GRENOBLE ALPES, SAINT MARTIN D'HERES (FR); INSTITUT POLYTECHNIQUE DE GRENOBLE, GRENOBLE (FR)

(72) Inventors: Kamal DANOUCHI, GRENOBLE (FR); Louis HUTIN, Grenoble (FR); Guillaume PRENAT, Grenoble (FR)

(21) Appl. No.: 19/425,970

(22) Filed: Dec. 18, 2025

(30) Foreign Application Priority Data
Dec. 26, 2024 (FR) 2415300

(51) Int. Cl. G06N 7/01; G11C 11/16

(52) U.S. Cl. CPC G06N 7/01; G11C 11/161; G11C 11/1673; G11C 11/1675

(57) ABSTRACT

A probabilistic bit generator includes: a magnetic tunnel junction having a resistance that fluctuates between at least two distinct resistive states depending on its magnetization; a bias circuit configured to inject a control current through the magnetic tunnel junction that varies depending on a first input voltage; the bias circuit including: a control transistor connected in series with the magnetic tunnel junction between two supply nodes and including an insulating layer buried in a semiconductor substrate forming a back gate; control means configured to apply the first input voltage to the back gate; a detection circuit configured to generate a detection signal that varies depending on the resistive state of the magnetic tunnel junction.

### CROSS-REFERENCE TO RELATED APPLICATION

This application claims priority to foreign French patent application No. FR 2415300, filed on Dec. 26, 2024, the disclosure of which is incorporated by reference in its entirety.

### FIELD OF THE INVENTION

The invention relates to a probabilistic-bit device based on a stochastic unit consisting of a magnetic tunnel junction. The invention relates more specifically to a particular control architecture for the stochastic unit that makes it possible to extend the input range of the probabilistic-bit device.

### BACKGROUND

A probabilistic bit generator is a device that randomly generates a bit word (0 or 1 binary outputs) based on physical or quantum phenomena, thus ensuring a determined level of randomness or entropy. Unlike conventional devices, which produce deterministic results, this type of device produces a 0 or 1 according to a probability able to be adjusted depending on the needs of the application. This type of probabilistic output is essential in fields such as cryptography, probabilistic algorithms and simulations, where the generation of random binary values guarantees the security or representativeness of calculations. This means that, rather than systematically giving a 0 or 1 deterministically, the device generates a bit word for a predetermined duration in which the distribution between 0 bits and 1 bits is able to be controlled or predefined via input parameters. For example, it would be possible to define a probability of 0.7 of obtaining a 1 and 0.3 of obtaining a 0, which would produce a distribution in a bit word in which roughly 70% of the bits are 1s and 30% are 0s. This probabilistic distribution distinguishes the probabilistic bit generator from pseudorandom number generators, because it relies on sources of physical uncertainty (such as quantum or thermal or magnetic noise), producing a true random in terms of bits.

Magnetic tunnel junction-based probabilistic bit generator devices are a promising solution for exploiting fluctuations in magnetic polarization state in such a structure. FIG. 1a illustrates the circuit diagram of a probabilistic bit generator D0 according to the prior art. The probabilistic bit generator D0 comprises a magnetic tunnel junction MTJ, a control transistor T₀ and a comparator COMP. The magnetic tunnel junction MTJ is a magnetoresistive pillar comprising a stack of layers 11, 12, 13. The stack comprises a first reference ferromagnetic layer 11 in which the direction of the magnetic polarization is set and uniform. The stack furthermore comprises a second ferromagnetic layer 13 in which the direction of the magnetic polarization is variable. The stack furthermore comprises an oxide barrier layer 12 confined between the first and second ferromagnetic layer 11, 13. The barrier layer 12 plays a crucial role in the magnetoresistive tunnelling effect, allowing electrons to pass through via quantum tunnelling. The first ferromagnetic layer 11 serves as a reference for detecting changes in magnetization in the free ferromagnetic layer 13. The operating principle of the magnetoresistive pillar MTJ is based on the change in electrical resistance as a function of the orientation of the magnetic polarization of the free ferromagnetic layer 13 with respect to the orientation of the magnetic polarization in the reference ferromagnetic layer 11. When the magnetizations of the free and reference layers 11, 13 are parallel, the electrical resistance is low, and reference is made to a low resistive state P. When the magnetizations are antiparallel, the electrical resistance is high, and reference is made to a high resistive state AP. The dimensioning of the magnetic tunnel junction MTJ is such that the magnetic moments of the layers fluctuate between various orientations under the influence of thermal fluctuations, even in the absence of an external magnetic field. These fluctuations are great enough, in relation to the energy barrier separating the two resistive states, for the magnetization no longer to be stable in a fixed direction. Reference is made here to operation in “fluctuation regime” or a “superparamagnetic” state, unlike magnetoresistive memories in which the magnetic layers retain their orientation following programming. Indeed, in a magnetoresistive memory, the energy barrier between the two resistive states is out of range of thermal energy with an amplitude greater than 40×k_{b}T, where k_{b} is the Boltzmann constant and T is the operating temperature of the memory. The operation of the superparamagnetic tunnel junction MTJ is illustrated by the energy diagram in FIG. 1 b, which illustrates a first resistive state P and a second resistive state AP separated by an energy barrier ΔE less than or equal to ten times the thermal energy k_{b}T, where k_{b} is the Boltzmann constant and T is the operating temperature of the generator D0. The respective probability of the magnetic tunnel junction MTJ generating 0 bits (high resistive state or vice versa, depending on the convention chosen) and 1 bits (low resistive state or vice versa, depending on the convention chosen) depends on the intensity of the bias current Ic passing through it. The intensity of the current Ic is regulated by the control transistor T₀ connected in series with the magnetic tunnel junction MTJ between a supply node supplying the supply voltage VDD and electrical ground GND. The comparator COMP is configured to compare the voltage drop across the magnetic tunnel junction with a reference voltage V_{REF}, in order to continuously determine the random resistive state of said magnetic tunnel junction.

The bias current Ic is controlled by the input voltage Vᵢₙ applied to the gate of the control transistor T₀. The control transistor T₀ is a CMOS transistor. The input voltage Vᵢₙ is advantageously chosen so as to operate in linear regime or in ohmic regime. Increasing the input voltage Vᵢₙ causes the bias current Ic to increase. Increasing the bias current Ic makes the probability P(1) of having a high resistive state AP (equivalent to a “1” bit, depending on the convention chosen) increase. Conversely, decreasing the bias current Ic makes the probability P(0) of having a low resistive state P (equivalent to a “0” bit, depending on the convention chosen) increase. One major technical problem is encountered in this context, namely that of limiting the input dynamic range for controlling the distribution of “1” and “0” in the generated bit sequence. Let V_{in,min} be the control voltage that makes it possible to obtain the distribution P(0)=99% P(1)=1%, where P(0) is the probability of having a 0 bit and P(1) is the probability of having a 1 bit. Let V_{in,max} max be the control voltage that makes it possible to obtain the distribution P(0)=1% P(1)=99%. The dynamic range of the input voltage Vᵢₙ is thus defined by V_{in,max}−V_{in,min}. In prior-art solutions, the input dynamic range is very small, with an amplitude less than or equal to 0.2 V. This drastically limits the stability and accuracy of the probabilistic bit generator.

To overcome the limitations of existing solutions, the invention proposes a probabilistic bit generator in which the tunnel junction is controlled by a voltage on the back gate of a transistor on SOI so as to extend the input dynamic range and thus have better control of the probability of obtaining a high or low resistive state. The generator according to the invention makes it possible to achieve dynamic ranges of the order of 1 V, this constituting a 5-fold extension compared to the dynamic ranges observed for solutions according to the prior art.

### SUMMARY OF THE INVENTION

The invention relates to a probabilistic bit generator comprising:
a magnetic tunnel junction having a resistance that fluctuates between at least two distinct resistive states depending on its magnetization;
a bias circuit configured to inject a control current through the magnetic tunnel junction that varies depending on a first input voltage; the bias circuit comprising:
a control transistor connected in series with the magnetic tunnel junction between two supply nodes and comprising an insulating layer buried in a semiconductor substrate forming a back gate;
control means configured to apply the first input voltage to said back gate;
a detection circuit configured to generate a detection signal that varies depending on the resistive state of the magnetic tunnel junction.

According to one particular aspect of the invention, the magnetic tunnel junction is a superparamagnetic tunnel junction.

According to one particular aspect of the invention, the control transistor is a fully depleted silicon on insulator transistor.

According to one particular aspect of the invention, the detection circuit is a comparator having a first input connected to a first end of the magnetic tunnel junction and a second input intended to receive a reference voltage and an output node for generating the detection signal.

According to one particular aspect of the invention, the generator furthermore comprises a computer circuit configured to generate a probabilistic bit from the detection signal based on sampling or averaging by determining the proportion of each resistive state of the magnetic tunnel junction during a predetermined period.

According to one particular aspect of the invention, the magnetic tunnel junction comprises:
a first reference ferromagnetic layer in which the direction of the magnetic polarization is set;
a second ferromagnetic layer in which the direction of the magnetic polarization is variable;
an oxide tunnel barrier layer confined between the first and second ferromagnetic layer.

According to one particular aspect of the invention, the thickness of the second layer is less than 10 nm.

According to one particular aspect of the invention, the diameter of the magnetic tunnel junction is less than 100 nm.

According to one particular aspect of the invention, the control transistor is diode-connected.

According to one particular aspect of the invention, the bias circuit is a current mirror comprising a first supply branch coupled to a second supply branch comprising at least the series-connected control transistor and magnetic tunnel junction.

According to one particular aspect of the invention, the first supply branch comprises a second control transistor having a second buried insulating layer forming an associated back gate, the control means being configured to apply a second input voltage to the back gate of the second control transistor.

### BRIEF DESCRIPTION OF THE DRAWINGS

Other features and advantages of the present invention will become more apparent on reading the following description in relation to the following appended drawings.

FIG. 1a illustrates a probabilistic bit generator D0 according to the prior art. This figure has already been described.

FIG. 1b illustrates an energy diagram of the probabilistic bit generator D0 according to the prior art. This figure has already been described.

FIG. 2a illustrates a probabilistic bit generator D1 according to a first embodiment of the invention.

FIG. 2b illustrates cross-sectional views of the implementation of four different FDSOI transistors.

FIG. 3 illustrates a probabilistic bit generator D1 according to a second embodiment of the invention.

FIG. 4 illustrates a probabilistic bit generator D1 according to a third embodiment of the invention.

FIG. 5 illustrates a probabilistic bit generator D1 according to a fourth embodiment of the invention.

FIG. 6 illustrates the probability of a high logic state “1” as a function of the input voltage for the generator according to the invention, compared to a generator according to the prior art.

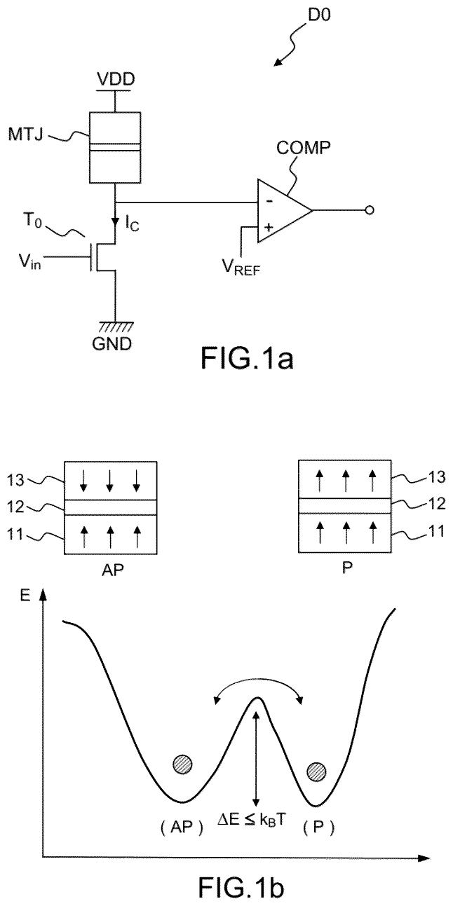

### DETAILED DESCRIPTION

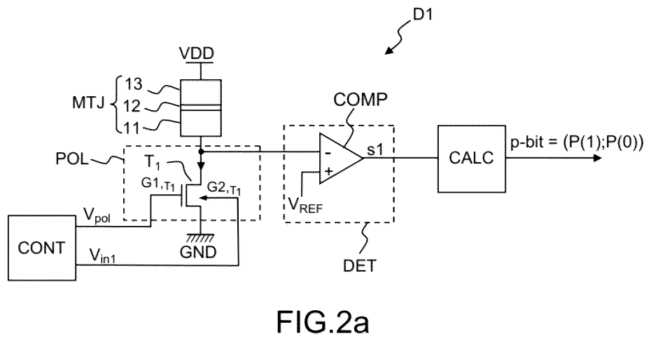

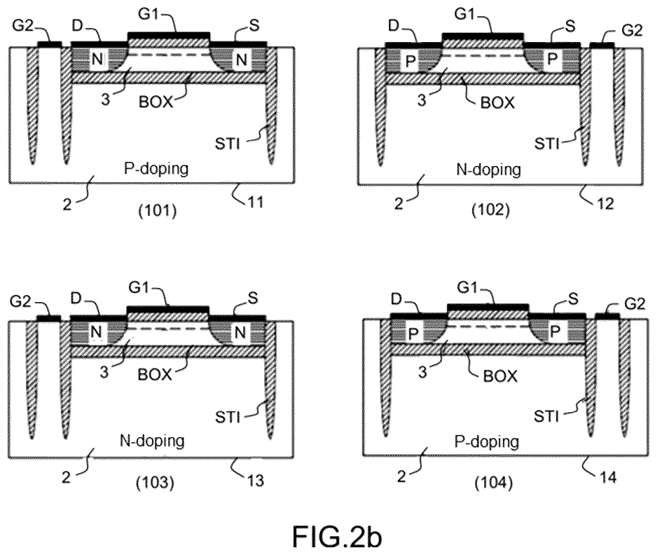

FIG. 2a illustrates a probabilistic bit generator D1 according to a first embodiment of the invention. The probabilistic bit p-bit generator D1 comprises a magnetic tunnel junction MTJ, a bias circuit POL, a detection circuit DET and a computer circuit CALC. The magnetic tunnel junction MTJ is dimensioned so as to operate in fluctuation regime in response to thermal agitation. The magnetic tunnel junction MTJ is formed by a stack of layers. The stack comprises a first reference ferromagnetic layer 11 in which the direction of the magnetic polarization is set and uniform. The stack furthermore comprises a second ferromagnetic layer 13 in which the direction of the magnetic polarization is variable. The stack furthermore comprises an oxide barrier layer 12 confined between the first and second ferromagnetic layer 11, 13. The diameter (or diagonal, depending on the shape) of the magnetic tunnel junction MTJ is less than 100 nm. More advantageously, the thickness of the second layer 13 is less than 10 nm. This makes it possible to lower the energy barrier separating the first resistive state P and the second resistive state AP to a value less than or equal to ten times the thermal energy k_{b}T, and therefore to produce a superparamagnetic tunnel junction MTJ. It will be recalled that a superparamagnetic tunnel junction has a fluctuating resistive state in which magnetization is unstable under thermal influence.

The bias circuit POL is configured to inject a control current Ic through the magnetic tunnel junction MTJ so as to control the distribution between the two resistive states of the superparamagnetic tunnel junction MTJ. The bias circuit POL is formed by a control transistor T₁ connected in series with the magnetic tunnel junction MTJ between a supply node supplying the supply voltage VDD and electrical ground GND. The control transistor T₁ is produced on an insulating layer buried in the substrate using silicon on insulator (SOI) technology, and more advantageously on a fully depleted silicon on insulator (FDSOI) substrate. To better understand the invention, FIG. 2b illustrates cross-sectional views of the implementation of four different FDSOI transistors. Diagram 101 is an NMOS regular voltage threshold (RVT) transistor 11. Diagram 102 is a PMOS regular voltage threshold (PMOS-RVT) FDSOI transistor 12. Diagram 103 is an NMOS low voltage threshold (LVT) FDSOI transistor 13. Diagram 104 is a PMOS low voltage threshold (PMOS-LVT) FDSOI transistor 14. The NMOS-RVT transistor 11 in diagram 101 employing FDSOI technology is produced on a P-doped semiconductor-based substrate 2. A layer of insulating dielectric material, generally an oxide denoted BOX, separates the assembly made up of the N-doped zones forming the drain D and the source S and the semiconductor region 3 containing the conduction channel from the rest of the substrate 2. A control gate G1 is obtained by stacking an oxide layer and a metal layer on the region 3 of the conduction channel, in a manner similar to a gate of a MOS transistor on a solid semiconductor substrate. Shallow trench isolations STI made of oxide are added to each side of the transistor 11 to electrically insulate the component. Layers of conductive material, generally made of metal, are deposited on the gate G1, the drain D and the source S to enable electrical connection to these terminals. In addition, an additional terminal G2 is added by depositing a metal layer on the region delimited by two shallow trench isolations STI adjacent to the transistor 11. Applying a voltage to the terminal G2 makes it possible to bias the buried oxide layer BOX, which acts as a back gate. This thus makes it possible to vary the threshold voltage Vₜₕ of the transistor 1. This operation is commonly referred to as back-biasing. The PMOS-RVT transistor 12 in diagram 102 has exactly the same structure as the one in diagram 101, except for the distribution of the doping, since it is a PMOS transistor. The substrate 2 is N-doped, and the drain D and the source S are P-doped. With regard to the NMOS-LVT transistor 13, the only difference from the transistor 11 in diagram 101 is the inversion of the doping type of the N-doped substrate 2. With regard to the PMOS-LVT transistor 14, the only difference from the transistor 12 in diagram 102 is the inversion of the doping type of the P-doped substrate 2. Generally speaking, the invention may be implemented with SOI transistors or with any transistor having an insulating layer buried in the substrate the conductance of which is able to be controlled via a back gate connected to the buried insulating layer.

In the probabilistic bit generator D1 according to the invention, increasing the bias current Ic makes the probability P(1) of having a high resistive state AP (equivalent to a “1” bit) increase. Conversely, decreasing the bias current Ic makes the probability P(0) of having a low resistive state P (equivalent to a “0” bit) increase. The bias current Ic is controlled by applying an input voltage Vᵢₙ₁ to the back gate G2,_{T1} of the control transistor T₁. The generator D1 comprises control means CONT configured to apply the variable input voltage Vᵢₙ₁ to the back gate G2,_{T1} and a fixed bias voltage V_{POL} to the front gate G1,_{T1} of the control transistor T₁. The bias voltage V_{POL} is chosen such that the control transistor operates in ohmic regime so as to ensure linear behaviour of the generator. Applying the input voltage Vᵢₙ₁ to the back gate G2,_{T1} makes it possible to modify the threshold voltage Vₜₕ of the transistor T₁, thereby enabling finer control of the variation of the control current Ic and thus more precise control of the distribution in the probabilistic bit p-bit. In the control transistor T₁, the back gate is formed by the buried dielectric layer BOX controlled by the terminal G2,_{T1}. The buried dielectric layer BOX has a much smaller capacitance compared to the front gate G1,_{T1} of the transistor T1. The thickness of the buried insulating layer BOX is less than or equal to 25 nm. The reduced capacitance enables more precise control of the biasing of the back gate G2,_{T1}, thereby enabling precise setting of the threshold voltage Vₜₕ of the control transistor T₁. As a result, by adjusting the voltage of the back gate G2,_{T1}, it becomes possible to obtain finer control of the positive slope of the sigmoid response at the output of the probabilistic bit generator, thus improving the overall sensitivity of the device. This results in a much wider input dynamic range V_{in,max}−V_{in,min}, with an amplitude of up to 1 V.

The control transistor T₁ may be an NMOS transistor or a PMOS transistor. The control transistor T₁ may be an LVT or RVT FDSOI transistor.

The detection circuit DET is configured to generate a detection signal s1 that varies depending on the resistive state of the magnetic tunnel junction MTJ. The detection circuit DET comprises a comparator COMP for comparing the voltage drop across the magnetic tunnel junction MTJ with a predetermined reference voltage V_{REF}. The magnetic tunnel junction MTJ and the control transistor T₁ form a voltage divider. The comparator COMP comprises a first input connected to the common node between the magnetic tunnel junction MTJ and the control transistor T₁; and a second input receiving the reference voltage V_{REF}. When the magnetic tunnel junction MTJ is in a high resistive state AP, the voltage received by the first input of the comparator is lower than the reference voltage V_{REF}, and the comparator generates an output voltage equal to VDD, equivalent to a bit equal to “1”. When the magnetic tunnel junction MTJ is in a low resistive state P, the voltage received by the first input of the comparator is greater than the reference voltage V_{REF}, and the comparator generates an output voltage equal to 0, equivalent to a bit equal to “0”.

As an alternative, the detection circuit DET comprises an inverter in place of the comparator COMP. The inverter comprises an input connected to the common node between the magnetic tunnel junction MTJ and the control transistor T₁. When the magnetic tunnel junction MTJ is in a high resistive state AP, the voltage received by the inverter is lower than its changeover threshold voltage. The inverter generates, on its output, an output signal equal to VDD, equivalent to a bit equal to “1”. When the magnetic tunnel junction MTJ is in a low resistive state P, the voltage received by the inverter is greater than its changeover threshold voltage, and the inverter generates an output voltage equal to 0, equivalent to a bit equal to “0”.

The computer circuit CALC is configured to generate a probabilistic bit from the detection signal s1 by determining the proportion of each resistive state of the magnetic tunnel junction MTJ during a predetermined period. The computer circuit is configured to compute the distribution between bits in a high logic state “1” and bits in a low logic state “0” in a bit sequence corresponding to the detection signal s1 for a predetermined duration. For example, the computer circuit CALC is configured to sample the detection output s1 every 1 ns during a period of 10 μs. The number of bits at “1” (or bits at “0”) is computed during the period of 10 μs, this corresponding to a sample of 10000 logic bits to determine the proportion of bits at “1” and at “0”, this corresponding to the probabilistic bit p-bit=(P(1), P(0)).

As an alternative, the computer circuit CALC is configured to compute the average of the detection signal s1 over the duration of the period. The average is proportional to the number of bits equal to “1” over the sampled period.

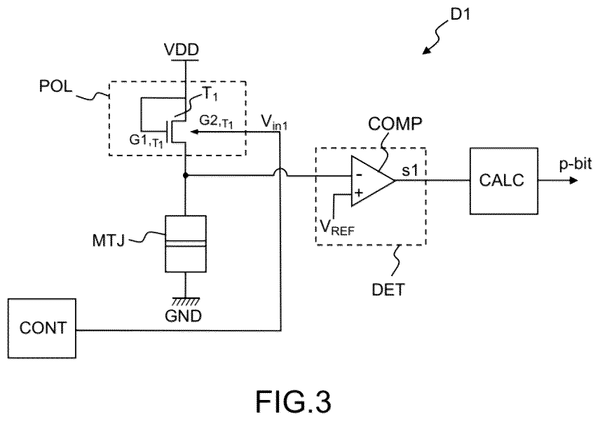

FIG. 3 illustrates a probabilistic bit generator D1 according to a second embodiment of the invention. The second embodiment has the same technical features and advantages described in detail for the first embodiment. The second embodiment differs from the first embodiment through the connection of the diode-connected control transistor T₁. The diode connection of the control transistor T₁ while at the same time maintaining the application of the input voltage Vᵢₙ₁ makes it possible to improve the stability and linearity of the generator D1 according to the invention.

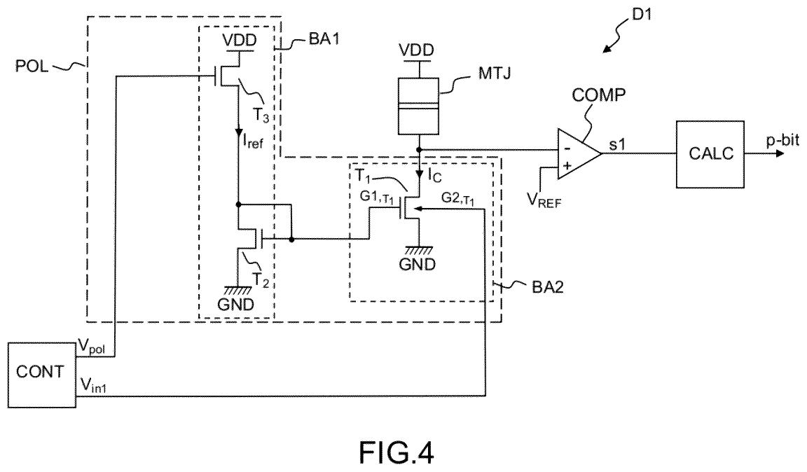

FIG. 4 illustrates a probabilistic bit generator D1 according to a third embodiment of the invention. The third embodiment has the same technical features and advantages described in detail for the first embodiment. In the generator D1 according to the third embodiment, the bias circuit POL is formed by a current mirror capable of copying a reference current to another branch of the circuit with high precision. The current mirror comprises a first supply branch BA1 coupled to a second supply branch BA2. The first branch comprises a PMOS transistor T3 connected in series with a diode-connected NMOS transistor T2. The transistor T3 receives a bias voltage V_{POL} on its front gate G1,_{T3} in order to set the intensity of I_{REF}. The front gate G1,_{T2} is connected to that of the control transistor T1 in order to couple the two supply branches BA1, BA2. The back gate G2,_{T1} of the control transistor T1 receives the input voltage Vᵢₙ₁ generated by the control circuit CONT, thereby making it possible to more precisely modulate the intensity of the current flowing through the second supply branch BA2 over a wider input dynamic range of up to 1 V.

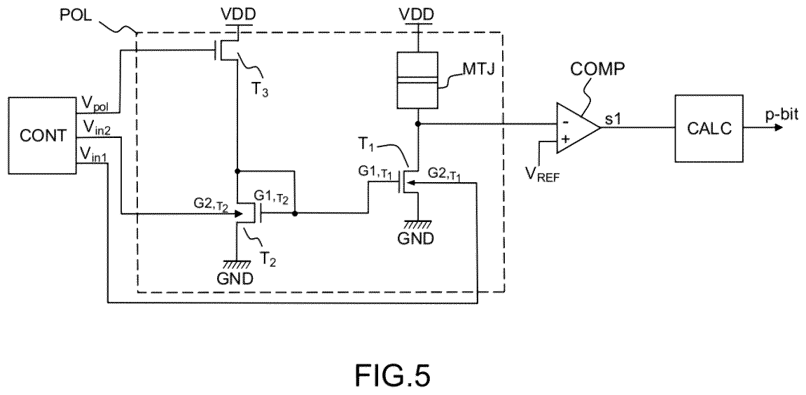

FIG. 5 illustrates a probabilistic bit generator D1 according to a fourth embodiment of the invention. The fourth embodiment has the same technical features and advantages described in detail for the third embodiment. In the generator D1 according to the fourth embodiment, the transistor T2 of the first branch also receives, on its back gate G2,_{T2}, a second input voltage Vᵢₙ₂ generated by the control circuit CONT. This makes it possible to obtain dual control of the probability of bits in the high logic state “1” in the generated bit sequence. This embodiment has the advantage of making it easier to find an operating point of the circuit when the bias voltage V_{POL} fluctuates by symmetrically adjusting the two transistors T1, T2 of the current mirror.

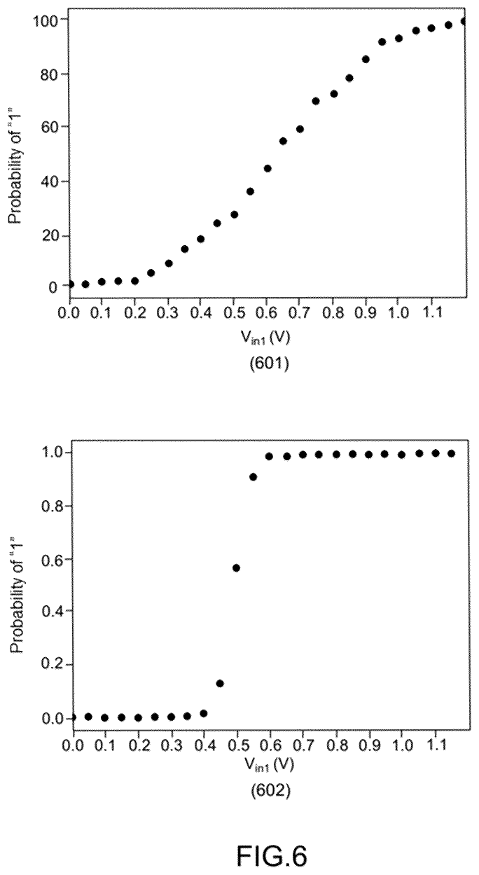

FIG. 6 illustrates the probability of a high logic state “1” as a function of the input voltage for the generator according to the invention on the curve (601) compared to a generator according to the prior art on the curve (602).

On the curve (602), the probability is almost zero for input voltage values Vᵢₙ between 0 V and 0.4 V. The probability is greater than 0.9 starting from an input voltage Vᵢₙ of 0.6 V. The input dynamic range observed for a generator according to the prior art is thus equal to 0.2 V. The slope of variation between the state P(1)=1% and P(1)=99% is steep, thereby limiting the possibility of controlling the output probability. On the curve (601), the probability is almost zero for input voltage values Vᵢₙ₁ between 0 V and 0.1 V. The probability is greater than 0.9 starting from an input voltage Vᵢₙ₁ of 1.1 V. The input dynamic range observed for a generator according to the invention is thus equal to 1.0 V. The slope of variation between the state P(1)=1% and P(1)=99% has been reduced, enabling more precise control of the output probability.

The probabilistic bit generator according to the invention exploits the stochastic properties of a magnetic tunnel junction MTJ to produce random or pseudorandom bits with a controlled distribution. Unlike conventional generators, it uses an SOI transistor, and more advantageously an FDSOI transistor, to precisely adjust the control current of the tunnel junction MTJ, thus modulating the probability of obtaining a high or low resistive state. This mechanism enables bit generation that is influenced directly by input voltage variations, providing a compact, precise and energy-efficient solution that is particularly suitable for integrated technologies. This innovation improves dynamic range and stability compared to existing solutions, thus expanding applications in cryptography, artificial intelligence and neuromorphic systems.

1. A probabilistic bit (p-bit) generator (D1) comprising:
a magnetic tunnel junction (MTJ) having a resistance that fluctuates between at least two distinct resistive states (P, AP) depending on its magnetization;
a bias circuit (POL) configured to inject a control current (Ic) through the magnetic tunnel junction (MTJ) that varies depending on a first input voltage (Vᵢₙ₁);
the bias circuit (POL) comprising:
a control transistor (T₁) connected in series with the magnetic tunnel junction (MTJ) between two supply nodes (VDD, GND) and comprising an insulating layer (BOX) buried in a semiconductor substrate (2) forming a back gate (G2,_{T1});
control means (CONT) configured to apply the first input voltage (Vᵢₙ₁) to said back gate (G2,_{T1});
a detection circuit (DET) configured to generate a detection signal (s1) that varies depending on the resistive state of the magnetic tunnel junction (MTJ).

2. The probabilistic bit (p-bit) generator (D1) according to claim 1, wherein the magnetic tunnel junction (MTJ) is a superparamagnetic tunnel junction.

3. The probabilistic bit (p-bit) generator according to claim 1, wherein the control transistor (T1) is a fully depleted silicon on insulator transistor.

4. The probabilistic bit (p-bit) generator (D1) according to claim 1, wherein the detection circuit (DET) is a comparator (COMP) having a first input connected to a first end of the magnetic tunnel junction (MTJ) and a second input intended to receive a reference voltage (V_{REF}) and an output node for generating the detection signal (s1).

5. The probabilistic bit (p-bit) generator (D1) according to claim 1, furthermore comprising a computer circuit (CALC) configured to generate a probabilistic bit from the detection signal (s1) based on sampling or averaging by determining the proportion of each resistive state of the magnetic tunnel junction (MTJ) during a predetermined period.

6. The probabilistic bit (p-bit) generator (D1) according to claim 1, wherein the magnetic tunnel junction (MTJ) comprises:
a first reference ferromagnetic layer wherein the direction of the magnetic polarization is set;
a second ferromagnetic layer wherein the direction of the magnetic polarization is variable;
an oxide tunnel barrier layer confined between the first and second ferromagnetic layer.

7. The probabilistic bit (p-bit) generator (D1) according to claim 6, wherein the thickness of the second layer is less than 10 nm.

8. The probabilistic bit (p-bit) generator (D1) according to claim 6, wherein the diameter of the magnetic tunnel junction (MTJ) is less than 100 nm.

9. The probabilistic bit (p-bit) generator (D1) according to claim 1, wherein the control transistor (T1) is diode-connected.

10. The probabilistic bit (p-bit) generator (D1) according to claim 1, wherein the bias circuit (POL) is a current mirror comprising a first supply branch (BA1) coupled to a second supply branch comprising at least the series-connected control transistor (T1) and magnetic tunnel junction (MTJ).

11. The probabilistic bit (p-bit) generator (D1) according to claim 10, wherein the first supply branch (BA1) comprises a second control transistor (T2) having a second buried insulating layer forming an associated back gate (G2,_{T2}), the control means (CONT) being configured to apply a second input voltage (Vᵢₙ₂) to the back gate (G2,_{T2}) of the second control transistor (T2).
